(19) United States
(12) Patent Application Publication
(10) Pub. No.: US 2026/0308805 A1
(43) Pub. Date: Oct. 8, 2026

(54) GALLIUM NITRIDE MATERIAL AND GALLIUM NITRIDE MATERIAL MANUFACTURING METHOD

(71) Applicant: SUMITOMO CHEMICAL COMPANY, LIMITED, Tokyo (JP)

(72) Inventors: Shota KANEKI, Ibaraki (JP); Hajime FUJIKURA, Ibaraki (JP); Yoshinobu NARITA, Ibaraki (JP)

(21) Appl. No.: 19/544,356

(22) Filed: Feb. 19, 2026

(30) Foreign Application Priority Data
Apr. 2, 2025 (JP) 2025-061284

(51) Int. Cl. C30B 29/40; C30B 25/16

(52) U.S. Cl. CPC C30B 29/40; C30B 25/16

(57) ABSTRACT

There is provided a gallium nitride material having at least a gallium nitride layer, wherein a photoluminescence measurement at room temperature shows that a ratio (I₂/I₁) of an emission intensity I₂ at a wavelength of plus 5 nm of a wavelength of a near-band-edge emission caused by a gallium nitride layer with respect to an emission intensity I₁ of the near-band-edge emission is 1.0 or more.

### BACKGROUND

### Technical Field

The present disclosure relates to a gallium nitride material and a gallium nitride material manufacturing method.

### Description of Related Art

A gallium nitride (GaN) device is being developed to realize a highly efficient optical and electronic device.

For example, Patent literature 1 discloses a technique for obtaining a high-quality semiconductor stack having a p-type layer. Also, for example, Non-Patent Literature 1 discloses a technique for quantifying an external quantum efficiency and an internal quantum efficiency of n-type GaN by a photoluminescence measurement.

### CITATION LIST

### Patent Literature

[Patent Literature 1] JP 2023-110417 A

### Non-Patent Literature

[Non-Patent Literature 1] Switching of major nonradiative recombination centers (NRCs) from carbon impurities to intrinsic NRCs in GaN crystals, Applied Physics Letters, 3 Jun. 2024

### SUMMARY OF THE INVENTION

### Technical Problem

One object of the present disclosure is to realize a high-performance GaN device.

### Solution to Problem

According to one aspect of the present disclosure, there is provided a gallium nitride material having at least a gallium nitride layer, wherein a photoluminescence measurement at room temperature shows that a ratio (I₂/I₁) of an emission intensity I₂ at a wavelength of plus 5 nm of an emission wavelength of a near-band-edge emission with respect to an emission intensity I₁ of the near-band-edge emission caused by the gallium nitride layer is 1.0 or more.

According to another aspect of the present disclosure, there is provided a gallium nitride material manufacturing method, including:
placing a substrate in a hydride vapor phase epitaxy apparatus;
growing a gallium nitride layer above the substrate using the hydride vapor phase epitaxy apparatus; and
quickly cooling the gallium nitride layer after growth,
wherein in the growing the gallium nitride layer, a temperature is increased at a rate of 30° C./min or more until reaching a growth temperature, and in the quickly cooling the gallium nitride layer, a temperature is decreased at a rate of 30° C./min or more during quick cooling.

### Advantageous Effects of Invention

According to the present disclosure, a high-performance GaN device can be realized.

### BRIEF DESCRIPTION OF THE DRAWINGS

FIG. 1 is a schematic cross-sectional view showing an example of a gallium nitride material according to a first embodiment of the present disclosure.

FIG. 2 is a flowchart showing an example of a gallium nitride material manufacturing method according to a first embodiment of the present disclosure.

FIG. 3 is a schematic view of a hydride vapor phase growth apparatus according to a first embodiment of the present disclosure.

FIG. 4 is a view showing the results of a photoluminescence measurement according to an example of the present disclosure.

### DETAILED DESCRIPTION OF THE INVENTION

### <Finding Obtained by the Inventors>

First, the findings obtained by the inventors will be explained.

It is known that a light emission efficiency can be improved by reducing a carbon concentration in a GaN crystal. However, as described in Non-Patent Literature 1, when the carbon concentration falls below a certain value (for example, 3.5×10¹⁴ cm⁻³ or less), a main factor hindering the light emission efficiency of GaN changes from carbon to point defects in the crystal. That is, in order to further improve the light emission efficiency of a GaN device, it is important not only to reduce the carbon concentration but also to suppress an occurrence of the point defects.

The inventors have conducted extensive research into the above-described problem. As a result, the inventors found that in a GaN crystal growth method using a hydride vapor phase epitaxy (HVPE) apparatus, the point defects can be suppressed by shortening a temperature rise time during crystal growth and quickly cooling the crystal after crystal growth.

Further, as a result of performing the photoluminescence measurement to the GaN crystal in which point defects have been suppressed in this way, the inventors found a new phenomenon.

In the photoluminescence measurement performed to the GaN crystal, it is known that LO phonon replica emission, which occurs when excitons transfer energy to LO phonons, is observed at a wavelength slightly longer than the wavelength of near-band-edge emission (hereinafter also referred to as NBE emission). In this specification, the emission wavelength of the LO phonon replica is defined as an emission wavelength of plus 5 mm of the NBE emission. It has been considered that a part of the NBE emission contributes to the emission of the LO phonon replica, and when the emission intensity of NBE emission is I₁ and the emission intensity of the LO phonon replica is I₂, it has been commonly accepted that I₁>I₂. In this specification, the emission intensity I₁ of the NBE emission is defined as a maximum emission intensity in a range of 361 to 363 nm in the photoluminescence measurement, and the emission wavelength at this time is defined as the emission wavelength of the NBE emission.

However, it was found that in the GaN crystal in which the point defects were suppressed by the above-described method, the emission intensity I₂ of the LO phonon replica was equal to or greater than the emission intensity I₁ of the NBE emission. On the other hand, the GaN crystal in which the emission intensity I₂ of the LO phonon replica emission is equal to or greater than the emission intensity I₁ of the NBE emission, is a high-purity crystal in which the point defects are suppressed, and can be said to be a crystal suitable for realizing a high-performance GaN device.

### DETAILS OF THE EMBODIMENT OF THE PRESENT DISCLOSURE

Next, one embodiment of the present disclosure will be described below with reference to the drawings. The present disclosure is not limited to these examples, but is defined by the scope of the claims, and is intended to include all modifications within the meaning and scope equivalent to the claims.

### First Embodiment of the Present Disclosure

### (1) Gallium Nitride Material 100

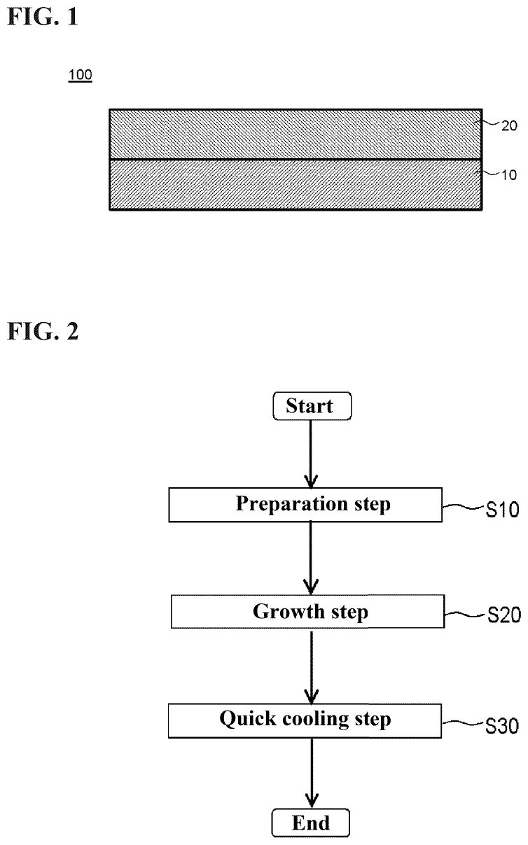

First, the configuration of the gallium nitride material 100 (GaN material 100) of this embodiment will be described. FIG. 1 is a schematic cross-sectional view showing an example of the GaN material 100 according to this embodiment. The GaN material 100 is, for example, a disc-shaped stack having a diameter of 50 mm or more, and is used when manufacturing a semiconductor device (GaN device). An upper limit of the diameter of the GaN material 100 is not particularly limited, but is, for example, 200 mm or less.

As shown in FIG. 1, the GaN material 100 includes, for example, a substrate 10 and a gallium nitride layer 20 (GaN layer 20) provided above the substrate 10.

The substrate 10 is a base material for growing the GaN layer 20. The substrate 10 is preferably composed of single crystal GaN.

A plane orientation of the main surface (the surface on which the GaN layer 20 is grown) of the substrate 10 is, for example, (0001) (+c plane). The GaN crystal constituting the substrate 10 may have a predetermined off-angle (for example, 0 degrees or more and 1.2 degrees or less) with respect to the main surface of the substrate 10.

The thickness of the substrate 10 is not particularly limited, but is, for example, 150 μm or more and 2000 μm or less.

The conductivity type of the substrate 10 is not particularly limited, but is, for example, n-type doped with Si.

The GaN layer 20 is composed of, for example, a single crystal of GaN provided above the substrate 10. The conductivity type of the GaN layer 20 is, for example, n-type, and contains almost no p-type impurities such as Mg. Specifically, the p-type impurity concentration in the GaN layer 20 is preferably 5×10¹⁴ cm⁻³ or less, and the effective carrier concentration is preferably 1×10¹⁴ cm⁻³ or more and 1×10¹⁷ cm⁻³ or less. When measuring the p-type impurity concentration in the GaN layer 20, for example, the Mg concentration may be measured by secondary ion mass spectrometry (SIMS). Further, when measuring the effective carrier concentration in the GaN layer 20, it is preferable to use a non-destructive measurement method such as mercury CV, electrochemical CV, or (corona-Kelvin probe) non-contact CV, from the viewpoint of performing the photoluminescence measurement described below.

The thickness of the GaN layer 20 is not particularly limited, but is, for example, 100 nm or more and 2000 μm or less.

Further, it is preferable that the C concentration in the GaN layer 20 is less than 5×10¹⁵ cm⁻³ and the Fe concentration is less than 1×10¹⁵ cm⁻³.

The GaN layer 20 is a GaN crystal in which the occurrence of the point defects is suppressed by a manufacturing method described below. However, it is very difficult to directly observe and evaluate the point defects in the GaN layer 20, and therefore in this embodiment, the point defects are evaluated by the photoluminescence measurement.

The photoluminescence measurement performed to the GaN material 100 of this embodiment at room temperature (e.g., 23° C.), shows that the ratio (I₂/I₁) of the emission intensity I₂ at the emission wavelength of the LO phonon replica (emission wavelength of plus 5 nm of the NBE emission) with respect to the emission intensity I₁ of the near-band-edge emission (NBE emission) caused by the GaN layer 20 is 1.0 or more. This means that the emission intensity I₂ of the LO phonon replica is equal to or greater than the emission intensity I₁ of the NBE emission. Such a GaN layer 20 is a highly pure crystal with reduced point defects, and can be said to be a crystal suitable for realizing a high-performance GaN device. An upper limit of the I₂/I₁ is not particularly limited, but is, for example, 2.0 or less.

Further, in the photoluminescence measurement performed to the GaN material 100 of this embodiment at room temperature, it is preferable that the emission wavelength at which the emission intensity caused by the GaN layer 20 is maximum, is plus 2 nm or more and plus 10 nm or less of the wavelength of the NBE emission. In most conventional GaN crystals, the emission wavelength at which the emission intensity is maximum, is the emission wavelength of the NBE emission (or the emission wavelength near the wavelength of the NBE emission). However, in the GaN material 100 of this embodiment, the emission wavelength at which the emission intensity is maximum, is shifted slightly to a longer wavelength side than the emission wavelength of the NBE emission. Specifically, the emission intensity becomes maximum at the emission wavelength of the LO phonon replica (or near the wavelength of the LO phonon replica). Such a GaN layer 20 is a highly pure crystal with reduced point defects, and can be said to be a crystal suitable for realizing a high-performance GaN device.

Further, when the photoluminescence measurement is performed to the GaN material 100 of this embodiment at room temperature, it is preferable that a wavelength range showing an emission intensity equal to or greater than the emission intensity I₁ of the NBE emission, exists continuously over at least 5 nm. As described above, in the GaN material 100 of this embodiment, the emission wavelength at which the emission intensity is maximum, is shifted slightly longer than the emission wavelength of the NBE emission, and therefore the wavelength range showing an emission intensity equal to or greater than the emission intensity I₁ of the NBE emission exists on the longer wavelength side than the emission wavelength of the NBE emission. Further, when the wavelength range is 5 nm or more, it shows that the point defects are further suppressed in the GaN layer 20. The upper limit of the wavelength range is not particularly limited, but is, for example, 20 nm or less.

In the photoluminescence measurement of the GaN crystal, it is known that emission of a secondary LO phonon replica (LO₂ phonon replica) is observed at a wavelength longer than the emission wavelength of the LO phonon replica. In this specification, the emission wavelength of the LO₂ phonon replica is defined as plus 17 nm of the wavelength of the NBE emission. The GaN material 100 of this embodiment has a higher emission intensity I₃ of the LO₂ phonon replica than a conventional GaN crystal. For example, when the photoluminescence measurement is performed to the GaN material 100 of this embodiment at room temperature, it is preferable that the ratio (I₃/I₁) of the emission intensity I₃ at the emission wavelength of the LO₂ phonon replica (the wavelength of plus 17 nm of the NBE emission) with respect to the emission intensity I₁ of the NBE emission is 0.15 or more. This shows that the point defects are further suppressed in the GaN layer 20. The upper limit of the I₃/I₁ is not particularly limited, but is, for example, 0.50 or less.

### (2) Method for Manufacturing the Gallium Nitride Material 100

Next, a method for manufacturing the GaN material 100 of this embodiment will be described. FIG. 2 is a flowchart showing an example of the method for manufacturing the GaN material 100 of this embodiment. As shown in FIG. 2, the method for manufacturing the GaN material 100 of this embodiment includes, for example, a preparation step S10, a growth step S20, and a quick cooling step S30.

### (Preparation Step S10)

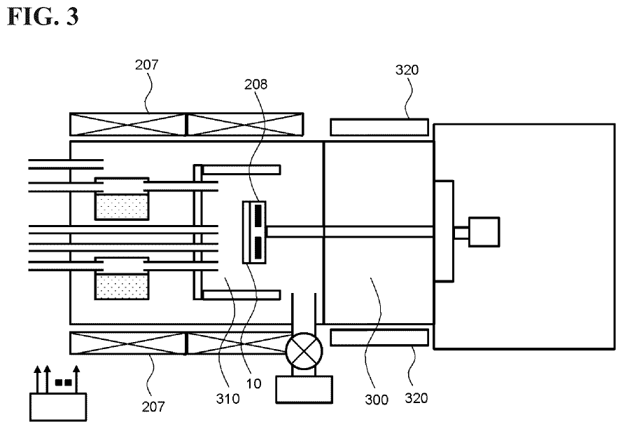

The preparation step S10 is, for example, a step of preparing a hydride vapor phase epitaxy (HVPE) apparatus and placing the substrate 10 in a reaction vessel (growth unit 310 for growing the GaN layer 20) in the HVPE apparatus. FIG. 3 is a schematic view of the HVPE apparatus used in this embodiment. As shown in FIG. 3, the HVPE apparatus of this embodiment includes a cooling unit 300 for quickly cooling the GaN layer 20 after growth. Other components of the HVPE apparatus can be publicly known, such as those described in Patent Literature 1, and therefore a description thereof will be omitted.

### (Growth Step S20)

The growth step S20 is a step of growing the GaN layer 20 above the substrate 10 using, for example, the HVPE apparatus. In this embodiment, an n-type GaN layer 20 doped with Si is grown.

In the growth step S20, the temperature is increased at a rate of 30° C./min or more until reaching the growth temperature of the GaN layer 20. To quickly increase the temperature, for example, in addition to heating the growth unit 310 with a heater 207 that is normally provided in the HVPE apparatus, induction heating may be performed to the susceptor 208 that holds the substrate 10 to locally heat the substrate 10. The upper limit of the rate of temperature rise until reaching the growth temperature of the GaN layer 20 is not particularly limited, but is, for example, 100° C./min or less.

### (Quick Cooling Step S30)

The quick cooling step S30 is, for example, a step of quickly cooling the GaN layer 20 (GaN material 100) after growth. In the quick cooling step S30, the temperature is decreased at a rate of 30° C./min or more during quick cooling. In addition to the quickly increasing the temperature at a rate of 30° C./min or more until reaching the growth temperature in the growth step S20, quick cooling at a rate of 30° C./min or more in the quick cooling step S30 can suppress the generation of the point defects in the GaN layer 20.

In the quick cooling step S30, it is preferable to move the substrate 10 (together with the susceptor 208) from the growth unit 310 for growing the GaN layer 20 to the cooling unit 300 for quickly cooling the GaN layer 20. Then, as shown in FIG. 3, it is preferable that the growth unit 310 and the cooling unit 300 are spatially separated. The cooling unit 300 may have a configuration covered with, for example, a water-cooling jacket 320. With such a configuration, heat from the growth unit 310 is less likely to propagate to the cooling unit 300, making it easier to quickly cool the GaN layer 20 and further suppressing the occurrence of the point defects.

Through the above steps, the GaN material 100 of this embodiment can be manufactured.

### Another Embodiment of the Present Disclosure

Although the embodiments of the present disclosure have been specifically described above, the present disclosure is not limited to the above-described embodiments and can be modified in various ways without departing from the gist of the present disclosure.

For example, in the above embodiment, the GaN material 100 is described as having the GaN layer 20 provided above the substrate 10, but the configuration of the GaN material 100 is not limited thereto, and it is sufficient if the GaN material 100 has at least the GaN layer 20. For example, the GaN material 100 may be a GaN free-standing substrate composed only of the GaN layer 20. Further, for example, the GaN material 100 may have other layers between the substrate 10 and the GaN layer 20, or other layers or films may be stacked (deposited) on the GaN layer 20.

Further, for example, in the above embodiment, the GaN layer 20 is of n-type, but the GaN layer 20 may be high-resistivity GaN doped with Fe, etc. In this case, the resistivity of the GaN layer 20 is preferably 10⁴ Ωcm or more, and more preferably 10⁷ Ωcm or more.

### EXAMPLES

Next, examples of the present disclosure will be described. These examples are merely examples of the present disclosure, and the present disclosure is not limited to these examples.

### (1) Manufacture of the GaN Material <Sample 1>

First, a GaN freestanding substrate was prepared as a substrate. The main surface of the substrate had a plane orientation of +c plane, a diameter of 2 inches (50.8 mm), and a thickness of 500 μm.

Next, the substrate was placed in the growth unit of the HVPE apparatus, and a Si-doped n-type GaN layer was grown above the substrate by the manufacturing method described in the above embodiment, to manufacture a GaN material (Sample 1). The GaN layer had a thickness of 10 μm and an effective carrier concentration of 1.8×10¹⁵ cm⁻³.

The following growth conditions were used for Sample 1:
Setting temperature of a heater 207: 800° C.
Setting temperature of a susceptor 208: 1000° C.
Processing pressure: 1 atmosphere
Partial pressure of GaCl gas: 1 kPa
Partial pressure of NH₃ gas/partial pressure of GaCl gas: 30
Partial pressure of H₂ gas/partial pressure of GaCl gas: 50

### <Sample 2>

First, a substrate similar to that used to manufacture Sample 1 was prepared.

Next, the substrate was placed in the growth unit of the conventional HVPE apparatus without a cooling unit, and a Si-doped n-type GaN layer was grown by a known method to manufacture a GaN material (Sample 2). The temperature was increased at a rate of less than 30° C./min until reaching the growth temperature of the GaN layer. After the GaN layer was grown, the temperature was slowly decreased within a growth area without quick cooling. The GaN layer had a thickness of 10 μm and an effective carrier concentration of 2.1×10¹⁵ cm⁻³.

### <Sample 3>

First, a substrate similar to that used to manufacture Sample 1 was prepared.

Next, a Si-doped n-type GaN layer was grown by metalorganic chemical vapor deposition (MOCVD) to manufacture a GaN material (Sample 3). The GaN layer had a thickness of 10 μm and an effective carrier concentration of 1.1×10¹⁵ cm⁻³

### (2) Photoluminescence Measurement

A photoluminescence measurement was performed at room temperature (23° C.) to the GaN layers of Samples 1 to 3. A light source was a HeCd laser (λ=325 nm) and an excitation light intensity was 6.538 W/cm². The results are shown in FIG. 3.

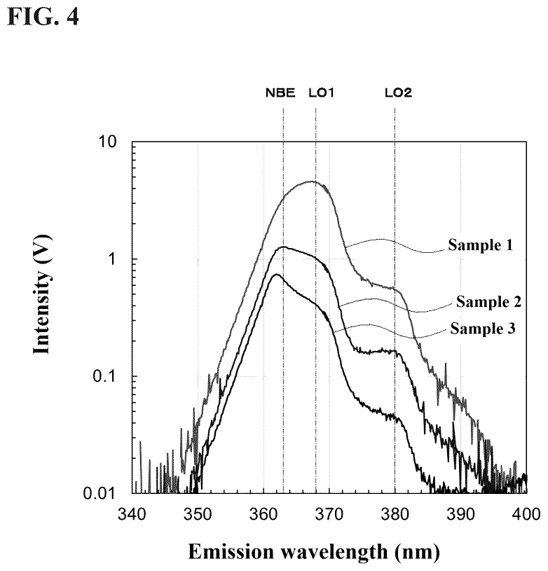

As shown in FIG. 4, in Samples 2 and 3, the emission intensity I₁ of the NBE emission (emission wavelength: 363 nm for Samples 1 and 2, and 362 nm for Sample 3) was greater than the emission intensity I₂ of the LO phonon replica (LO1) emission (emission wavelength: 368 nm for Samples 1 and 2, and 367 nm for Sample 3). In contrast, in Sample 1 manufactured by the method of the present disclosure, the emission intensity I₂ of the LO phonon replica was greater than the emission intensity I₁ of the NBE emission. The lines showing the emission wavelengths of NBE, LO1, and LO2 shown in FIG. 4 are for the emission wavelengths of Sample 1 respectively.

Specifically, an I₂/I₁ ratio of Sample 1 was 1.40, an I₂/I₁ ratio of Sample 2 was 0.83, and an I₂/I₁ ratio of Sample 3 was 0.61. Further, when the emission intensity of the LO₂ phonon replica (LO₂) emission (emission wavelength 380 nm for Samples 1 and 2, and 379 nm for Sample 3) is defined as I₃, an I₃/I₁ ratio for Sample 1 was 0.17, the I₃/I₁ ratio for Sample 2 was 0.13, and the I₃/I₁ ratio for Sample 3 was 0.06. That is, Sample 1 had larger values of I₂/I₁ and I₃/I₁ than Samples 2 and 3.

### (3) Manufacture of the GaN Device

GaN devices (PN junction diodes) were manufactured using the GaN materials of Samples 1 to 3, and the on-resistance and failure rate of these devices were investigated. The results are shown in Table 1.

TABLE 1

| | Sample 1 | Sample 2 | Sample 3 |
|---|---|---|---|
| Carrier concentration | 1.8E15/cm3 | 2.1E15/cm3 | 1.1E15/cm3 |
| LO1 intensity ratio | 1.40 | 0.83 | 0.61 |
| (I2/I1) | | | |
| LO2 intensity ratio | 0.17 | 0.13 | 0.06 |
| (I3/I1) | | | |
| On-resistance | 6 mΩ · cm2 | 10 mΩ · cm2 | 11 mΩ · cm2 |
| Failure rate | 4% | 23% | 25% |

As shown in Table 1, the device of Sample 1 had a dramatically improved on-resistance and an improved failure rate compared to the devices of Samples 2 and 3.

As described above, it was confirmed that by the method of the present disclosure, the GaN material in which the emission intensity of the LO phonon replica is equal to or greater than the emission intensity of the NBE emission, can be manufactured. It was also confirmed that such a GaN material is a suitable crystal for realizing a high-performance GaN device.

### Preferable Aspects of the Present Disclosure

Preferable aspects of the present disclosure will be described below.

### (Supplementary Description 1)

There is provided a gallium nitride material having at least a gallium nitride layer,
wherein a photoluminescence measurement at room temperature shows that a ratio (I₂/I₁) of an emission intensity I₂ at a wavelength of plus 5 nm of a wavelength of a near-band-edge emission caused by a gallium nitride layer with respect to an emission intensity I₁ of the near-band-edge emission is 1.0 or more.

### (Supplementary Description 2)

The gallium nitride material according to Supplementary description 1,
wherein the gallium nitride layer has a p-type impurity concentration of 5×10¹⁴ cm⁻³ or less and an effective carrier concentration of 1×10¹⁷ cm⁻³ or less.

### (Supplementary Description 3)

The gallium nitride material according to Supplementary description 1,
wherein, the photoluminescence measurement performed at room temperature shows that the emission wavelength at which the emission intensity caused by the gallium nitride layer is maximum, is plus 2 nm or more and plus 10 nm or less of the wavelength of the near-band-edge emission.

### (Supplementary Description 4)

The gallium nitride material according to Supplementary description 1,
wherein the photoluminescence measurement performed at room temperature shows that a wavelength range showing an emission intensity equal to or greater than the emission intensity I₁ exists over at least 5 nm.

### (Supplementary Description 5)

The gallium nitride material according to Supplementary description 1,
wherein the photoluminescence measurement performed at room temperature shows that a ratio (I₃/I₁) of an emission intensity I₃ at a wavelength of plus 17 nm of the wavelength of the near-band-edge emission with respect to the emission intensity I₁ is 0.15 or more.

### (Supplementary Description 6)

A gallium nitride material according to supplementary description 1,
wherein a C concentration is less than 5×10¹⁵ cm⁻³ and a Fe concentration is less than 1×10¹⁵ cm⁻³ in the gallium nitride layer.

### (Supplementary Description 7)

The gallium nitride material according to any one of Supplementary descriptions 1 to 6, having a diameter of 50 mm or more.

### (Supplementary Description 8)

A gallium nitride material manufacturing method, including:
placing a substrate in a hydride vapor phase epitaxy apparatus;
growing a gallium nitride layer above the substrate using the hydride vapor phase epitaxy apparatus; and
quickly cooling the gallium nitride layer after growth,
wherein in the growing the gallium nitride layer, a temperature is increased at a rate of 30° C./min or more until reaching a growth temperature, and in the quickly cooling the gallium nitride layer, a temperature is decreased at a rate of 30° C./min or more during quick cooling.

### (Supplementary Description 9)

The gallium nitride material manufacturing method according to Supplementary description 8,
wherein in the quickly cooling the gallium nitride layer, the substrate is moved from a growth unit for growing the gallium nitride layer to a cooling unit for quickly cooling the gallium nitride layer, and the growth unit and the cooling unit are spatially separated.

1. A gallium nitride material having at least a gallium nitride layer,
wherein a photoluminescence measurement at room temperature shows that a ratio (I₂/I₁) of an emission intensity I₂ at a wavelength of plus 5 nm of a wavelength of a near-band-edge emission caused by a gallium nitride layer with respect to an emission intensity I₁ of the near-band-edge emission is 1.0 or more.

2. The gallium nitride material according to claim 1, wherein the gallium nitride layer has a p-type impurity concentration of 5×10¹⁴ cm⁻³ or less and an effective carrier concentration of 1×10¹⁷ cm⁻³ or less.

3. The gallium nitride material according to claim 1,
wherein, the photoluminescence measurement performed at room temperature shows that an emission wavelength at which the emission intensity caused by the gallium nitride layer is maximum, is plus 2 nm or more and plus 10 nm or less of the wavelength of the near-band-edge emission.

4. The gallium nitride material according to claim 1,
wherein the photoluminescence measurement performed at room temperature shows that a wavelength range showing an emission intensity equal to or greater than the emission intensity I₁ exists over at least 5 nm.

5. The gallium nitride material according to claim 1,
wherein the photoluminescence measurement performed at room temperature shows that a ratio (I₃/I₁) of an emission intensity I₃ at a wavelength of plus 17 nm of the wavelength of the near-band-edge emission with respect to the emission intensity I₁ is 0.15 or more.

6. A gallium nitride material according to claim 1,
wherein a C concentration is less than 5×10¹⁵ cm⁻³ and a Fe concentration is less than 1×10¹⁵ cm⁻³ in the gallium nitride layer.

7. The gallium nitride material according to claim 1, having a diameter of 50 mm or more.

8. A gallium nitride material manufacturing method, comprising:
placing a substrate in a hydride vapor phase epitaxy apparatus;
growing a gallium nitride layer above the substrate using the hydride vapor phase epitaxy apparatus; and
quickly cooling the gallium nitride layer after growth,
wherein in the growing the gallium nitride layer, a temperature is increased at a rate of 30° C./min or more until reaching a growth temperature, and in the quickly cooling the gallium nitride layer, a temperature is decreased at a rate of 30° C./min or more during quick cooling.

9. The gallium nitride material manufacturing method according to claim 8,
wherein in the quickly cooling the gallium nitride layer, the substrate is moved from a growth unit for growing the gallium nitride layer to a cooling unit for quickly cooling the gallium nitride layer, and the growth unit and the cooling unit are spatially separated.
